(19) United States
(12) Patent Application Publication
(10) Pub. No.: US 2004/0171236 A1
(43) Pub. Date: Sep. 2, 2004

(54) Method for reducing surface roughness of polysilicon films for liquid crystal displays

(75) Inventors: Chu-Jung Shih, Miao-Li Country (TW); Yaw-Ming Tsai, Miao-Li Country (TW)

Correspondence Address: Finnegan, Henderson, Farabow,, Garrett & Dunner, L.LP., 1300 I Street, N.W., Washington, DC, 20005-3315, US

(73) Assignee: Toppoly Electronics Corp.

(21) Appl. No.: 10/796,343

(22) Filed: Mar. 10, 2004

Related U.S. Application Data
(63) Continuation-in-part of application No. 10/226,110, filed on Aug. 23, 2002.

(51) Int. Cl. H01L 21/326

(52) U.S. Cl. 438/478

(57) ABSTRACT

A semiconductor method for a liquid crystal display that includes providing a substrate, providing a layer of insulating material over the substrate, depositing a layer of amorphous silicon over the layer of insulating material, crystallizing the layer of amorphous silicon to form a layer of polysilicon, treating the layer of polysilicon to change the properties of a surface of the layer of polysilicon, and smoothing the surface of the layer of polysilicon.

### RELATED APPLICATION

This application is a continuation-in-part application and claims priority to U.S. application Ser. No. 10/226,110, entitled “Method for Reducing Surface Roughness of Polysilicon Films for Liquid Crystal Displays,” filed on Aug. 23, 2002, the entire contents of which are expressly incorporated herein by reference.

### FIELD OF THE INVENTION

The invention generally pertains to a method for manufacturing a polysilicon semiconductor layer in a liquid crystal display and, more particularly, to a method for manufacturing a polysilicon semiconductor layer with reduced surface roughness.

### BACKGROUND OF THE INVENTION

In the development of thin film transistor (“TFT”) liquid crystal display (“LCD”) technology, polycrystalline silicon, or polysilicon, has become a semiconductor layer of choice over amorphous silicon. In the manufacturing process, a layer of amorphous silicon is first deposited over an insulating substrate. The layer of amorphous silicon may be crystallized through a number of conventional methods, including excimer laser annealing (“ELA”) at a low temperature, solid phase crystallization (“SPC”) at a high temperature, continuous grain growth (“CGG”), metal induced crystallization (“MIC”), metal induced lateral crystallization (“MILC”), and sequential lateral solidification (“SLS”).

An important consideration in the crystallization process is the grain size of the polycrystalline. If the grain size is too small, the polysilicon layer will exhibit low electron mobility and high resistance, each of which may adversely affect the electrical characteristics of the TFT LCD. Specifically, low electron mobility and high resistance may prevent pixel capacitors from being sufficiently charged, which may prevent display contrast from being accurately displayed, or cause errors in the operation of periphery driver circuits.

However, a polysilicon layer having a large grain size exhibits a rough surface, and the surface roughness increases as the grain size increases. In the TFT LCD manufacturing process, a gate insulator layer is formed over the polysilicon layer. The gate insulator layer generally is an oxide layer (SiO₂) grown over the polysilicon layer. As a result, the roughness of the polysilicon surface will determine the characteristics of the gate insulator layer. In addition, if the surface is too rough, a concentration of electrical field is created at the peak of the ridges on the polysilicon surface, which gives rise to leakage current. A leakage current in a pixel will adversely change the threshold voltage of the LCD pixels.

### SUMMARY OF THE INVENTION

In accordance with the invention, there is provided a semiconductor method for a liquid crystal display that includes providing a substrate, providing a layer of insulating material over the substrate, depositing a layer of amorphous silicon over the layer of insulating material, crystallizing the layer of amorphous silicon to form a layer of polysilicon, treating the layer of polysilicon to change the properties of a surface of the layer of polysilicon, and smoothing the surface of the layer of polysilicon.

In one aspect, treating the layer of polysilicon includes forming a native oxide layer over the layer of polysilicon and increasing a thickness of the native oxide layer.

In another aspect, treating the layer of polysilicon includes forming a layer of oxide over the layer of polysilicon.

In accordance with the present invention, there is also provided a method for making semiconductor device that includes forming an insulating layer over a substrate; forming an amorphous silicon layer over the insulating layer; forming a polysilicon layer by crystallizing the amorphous silicon layer; changing properties of a surface of the polysilicon layer; and smoothing a surface of the changed polysilicon layer.

In accordance with the present invention, there is further provided a method for making semiconductor device that includes forming an insulating layer over a substrate; forming an amorphous layer over the insulating layer; forming a polysilicon layer using the amorphous layer; oxidizing a surface of the polysilicon layer; and etching the oxidized surface of the polysilicon layer to provide a smooth surface for the polysilicon layer.

Additional objects and advantages of the invention will be set forth in part in the description which follows. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawing, which is incorporated in and constitutes a part of this specification, illustrates embodiments and together with the description, serves to explain the principles of the claimed invention.

### BRIEF DESCRIPTION OF THE DRAWINGS

FIG. 1 is a cross-sectional view of an exemplary manufacturing process consistent with the present invention.

### DESCRIPTION OF THE EMBODIMENTS

Reference will now be made in detail to the present embodiments, examples of which are illustrated in the accompanying drawing.

Generally, during the crystallization process of an amorphous silicon layer, polysilicon dislocation is one of the main causes for the formation of a rough surface on a polysilicon layer. Dislocation of polysilicon crystalline usually occurs at the grain boundary. In addition, the crystallization process around the location where there is polysilicon dislocation is worse than other locations, resulting in a high concentration of dangling bonds. However, the dangling bonds are more conducive to the oxidation process, creating silicon oxides having a higher density compared to the silicon oxides produced elsewhere. Therefore, the following embodiments overcome such limitations in which a method is disclosed for silicon crystallization by producing or increasing the thickness of a silicon oxide formed on the polysilicon layer surface, followed by removing the silicon oxide, to reduce the surface roughness of the polysilicon layer.

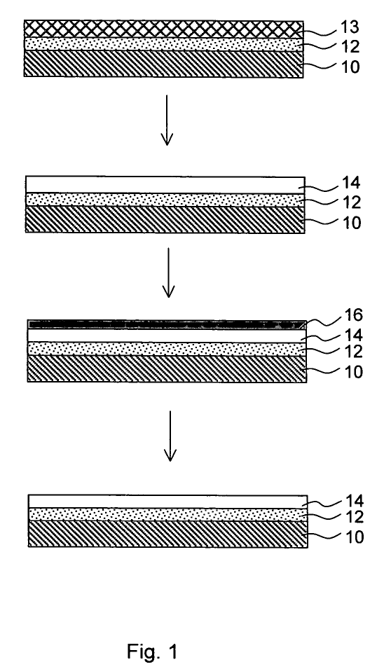

FIG. 1 is a flow chart of the manufacturing process consistent with the present invention. Referring to FIG. 1, a substrate 10 is provided and defined. A first layer of insulating material 12 may be provided over the substrate 10. A silicon layer 13 is formed over the insulating material 12. Specifically, a layer of amorphous silicon 13 is deposited over the insulating material 12. The layer of amorphous silicon 13 may be deposited with any conventional deposition method. As discussed in further detail below, the deposition of amorphous silicon 13 may use different processing steps according to different embodiments.

For example, according to a first embodiment of the present invention, the layer of amorphous silicon 13 is crystallized, and a oxide layer 16 is formed over the silicon layer 14. The crystallization process is performed in an oxygen environment to induce simultaneous oxidation on the surface of the silicon layer 14 to reduce surface roughness of the silicon layer 14. The crystallization may be performed in an oxygen environment and accompanying with ashing, ozone (O₃), excimer ultraviolet light (“EUV”), or rapid thermal processing (“RTP”), or in an oven or hot plate at an elevated temperature. During the crystallization process, the oxide layer 16 is first formed as a native oxide. The thickness of the oxide layer 16 may be increased and controlled through the duration of the crystallization process.

The surface roughness of the silicon layer 14 may be further reduced by etching back the oxide layer 16 with buffer hydrogen-fluoride (BHF), diluted HF (DHF), or dry etch. The oxide layer 16 may be etched back partially or completely. If the oxide layer 16 is completely etched back, an additional oxidation step will be performed to form a gate insulator over the silicon layer 14.

According to a second embodiment, the layer of amorphous silicon 13 is first crystallized using a conventional method to form polysilicon layer 14. In one aspect, polysilicon layer 14 has a rough surface. Then, the rough surface of polysilicon layer 14 is treated to change the properties thereof, and the treated surface is smoothed. In one aspect, the poly-silicon layer 14 is treated in an oxygen environment, such as be performed with ashing, ozone (O₃), excimer ultraviolet light (“EUV”), or rapid thermal processing (“RTP”) environments, or in an oven or hot plate at an elevated temperature. Consequently, an oxide layer 16 is formed on polysilicon layer 14. Oxide layer 16 is then removed by etching with buffered hydrogen-fluoride (BHF), diluted HF (DHF), or dry etch. Oxide layer 16 may be etched back partially or completely. As a result of etching oxide layer 16, the surface of polysilicon layer 14 is smoothed.

According to a third embodiment, the layer of amorphous silicon 14 is first crystallized using a conventional method to form polysilicon layer 14, which has a rough surface. In one aspect, substrate 10 with insulating layer 12 and polysilicon layer 14 formed thereon is left in the atmosphere, and a native oxide 16 is formed on polysilicon layer 14. A thickness of native oxide 16 may increased by leaving substrate 10 in the atmosphere for a prolonged period of time. Oxide layer 16 is then removed by etching with buffer hydrogen-fluoride (BHF), diluted HF (DHF), or dry etch. Oxide layer 16 may be etched back partially or completely. As a result of etching oxide layer 16, the surface of polysilicon layer 14 is smoothed.

After the surface of polysilicon layer 14 is smoothed, conventional processing steps (not shown) are performed to form devices on the substrate. For example, a gate insulating layer may be formed over the polysilicon layer.

In the above embodiments, any number of variations or combinations of the disclosed techniques can be implemented to increase or change the thickness of the silicon oxide and to smooth the polysilicon surface. For example, an oxide layer can be formed on the polysilicon layer and etched back completely and then another oxide layer is formed and etched back partially.

Furthermore, other embodiments may be contemplated from consideration of the specification. Therefore it is intended that the specification and examples be considered as exemplary only, with a true scope and spirit of the invention being indicated by the following claims.

What is claimed is:

1. A semiconductor method for a liquid crystal display, comprising:
providing a substrate;
providing a layer of insulating material over the substrate;
depositing a layer of amorphous silicon over the layer of insulating material; and
crystallizing the layer of amorphous silicon to form a layer of polysilicon;
treating the layer of polysilicon to change the properties of a surface of the layer of polysilicon;
smoothing the surface of the layer of polysilicon.

2. The method as claimed in claim 1, wherein treating the layer of polysilicon is performed in an environment of ashing, ozone, excimer UV light, oven, hot plate, or rapid thermal processing.

3. The method as claimed in claim 2, wherein smoothing the surface of the layer of polysilicon comprises etching the surface of the layer of polysilicon with one of buffered hydrogen-fluoride, diluted hydrogen-fluoride, or dry etch.

4. The method as claimed in claim 1, wherein treating the layer of polysilicon includes forming a native oxide layer over the layer of polysilicon and increasing a thickness of the native oxide layer.

5. The method as claimed in claim 4, wherein increasing the thickness of the native oxide comprises leaving the substrate with the polysilicon formed thereon in the atmosphere for a period of time.

6. The method as claimed in claim 4, wherein smoothing the surface of the layer of polysilicon comprises etching the surface of the layer of polysilicon with one of buffered hydrogen-fluoride, diluted hydrogen-fluoride, or dry etch.

7. The method as claimed in claim 1, wherein treating the layer of polysilicon includes forming a layer of oxide over the layer of polysilicon.

8. The method as claimed in claim 7, wherein the layer of oxide is formed in performed in an environment of ashing, ozone, excimer UV light, oven, hot plate, or rapid thermal processing.

9. The method as claimed in claim 7, wherein smoothing the surface of the layer of polysilicon comprises etching the layer of oxide with one of buffered hydrogen-fluoride, diluted hydrogen-fluoride, or dry etch

10. A method for making semiconductor device, comprising:
forming an insulating layer over a substrate;
forming an amorphous silicon layer over the insulating layer;
forming a polysilicon layer by crystallizing the amorphous silicon layer;
changing properties of a surface of the polysilicon layer; and
smoothing a surface of the changed polysilicon layer.

11. The method as claimed in claim 10, wherein changing the properties of a surface of the polysilicon layer includes treating the polysilicon layer in an environment of ashing, ozone, excimer UV light, oven, hot plate, or rapid thermal processing.

12. The method as claimed in claim 11, wherein smoothing a surface of the changed polysilicon layer comprises etching the surface of the polysilicon layer with one of buffered hydrogen-fluoride, diluted hydrogen-fluoride, or dry etch.

13. The method as claimed in claim 10, wherein changing properties of a surface of the polysilicon layer includes forming a native oxide layer over the polysilicon layer and increasing a thickness of the native oxide layer.

14. The method as claimed in claim 13, wherein increasing the thickness of the native oxide comprises leaving the substrate with the polysilicon formed thereon in the atmosphere for a period of time.

15. The method as claimed in claim 13, wherein smoothing a surface of the changed polysilicon layer comprises etching the surface of the layer of polysilicon with one of buffered hydrogen-fluoride, diluted hydrogen-fluoride, or dry etch.

16. The method as claimed in claim 10, wherein changing properties of a surface of the polysilicon layer includes forming an oxide layer over the layer of polysilicon.

17. The method as claimed in claim 16, wherein the oxide layer is formed in an environment of ashing, ozone, excimer UV light, oven, hot plate, or rapid thermal processing.

18. The method as claimed in claim 16, wherein smoothing a surface of the changed polysilicon layer comprises etching the layer of oxide with one of buffered hydrogen-fluoride, diluted hydrogen-fluoride, or dry etch.

19. A method for making semiconductor device, comprising:
forming an insulating layer over a substrate;
forming an amorphous layer over the insulating layer;
forming a polysilicon layer using the amorphous layer;
oxidizing a surface of the polysilicon layer; and
etching the oxidized surface of the polysilicon layer to provide a smooth surface for the polysilicon layer.
